(19) United States
(12) Patent Application Publication
(10) Pub. No.: US 2024/0349576 A1
(43) Pub. Date: Oct. 17, 2024

(54) DISPLAY MODULE AND MANUFACTURING METHOD THEREOF, AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Defu ZHU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/250,991

(22) PCT Filed: Mar. 24, 2023
(86) PCT No.: PCT/CN2023/083901

§ 371 Date: Apr. 28, 2023

(30) Foreign Application Priority Data
Feb. 28, 2023 (CN) 202310194891.8

(51) Int. Cl. H10K 59/80; H10K 59/12; H10K 59/38; H10K 59/65

(52) U.S. Cl. CPC H10K 59/873; H10K 59/1201; H10K 59/38; H10K 59/65; H10K 59/8792

(57) ABSTRACT

A display module and a manufacturing method thereof, and a display device. The display module includes a display area and a function area. The display module includes a display panel, a cover plate layer, a filter layer, a flexible composite layer, and a shielding layer. The flexible composite layer is located between the filter layer and the cover plate layer, and the flexible composite layer includes a first adhesive layer and a transparent film layer. The shielding layer includes a first shielding part located in the function area. A function hole located in the function area goes through the display panel, the filter layer, the first adhesive layer, the transparent film layer, and the first shielding.

### TECHNICAL FIELD

The present application relates to a field of display technology, and particularly relates to a display module and a manufacturing method thereof, and a display device.

### BACKGROUND

For folding display screens, it is necessary to dispose a circle of ink around a camera hole to shield circuits around the camera hole. The folding display screens are formed by polymer films and optically clear adhesives stacked with different materials. A hardness of each layer of the polymer films and the optically clear adhesives is poor, and it is easy to deform during a bonding process. Particularly, a camera part is prone to relatively high deformation due to an uneven ink thickness, which has a thickness difference with other parts, resulting in a local high peroxide value (PV), thereby affecting a photographing effect of a whole machine.

### SUMMARY

### Technical Problems

The present application provides a display module and a manufacturing method thereof, and a display device to solve a technical problem that an existing camera part is prone to relatively high deformation due to an uneven ink thickness, which has a thickness difference with other parts, resulting in a local high peroxide value (PV), thereby affecting a photographing effect of a whole machine.

### Technical Solutions

In order to solve the problem above-mentioned, technical solutions provided by the present application are as follows:

The present application provides a display module, provided with a display area and a function area surrounded by the display area; the display module including:
a display panel;
a cover plate layer located on a light-emitting side of the display panel;
a filter layer located on a side of the display panel adjacent to the cover plate layer, the filter layer includes a plurality of color filters and black matrixes disposed between two adjacent color filters;
a flexible composite layer located between the filter layer and the cover plate layer, the flexible composite layer includes a first adhesive layer and a transparent film layer disposed on a side of the first adhesive layer away from the display panel;
a shielding layer located between the filter layer and the cover plate layer, the shielding layer includes a first shielding part located in the function area and in contact with a side surface of the transparent film layer;
the display module further includes a function hole which is defined in the function area, the function hole goes through the display panel, the filter layer, the first adhesive layer, the transparent film layer, and the first shielding part in a first direction, where the first direction is a thickness direction of the display module.

According to the display module provided by the present application, the first shielding part is located between the first adhesive layer and the transparent film layer, or the first shielding part is located on a side of the transparent film layer away from the display panel.

According to the display module provided by the present application, the flexible composite layer further includes a second adhesive layer located on the side of the transparent film layer away from the display panel, and the function hole goes through the display panel, the first adhesive layer, the transparent film layer, the first shielding part, and the second adhesive layer in the first direction.

According to the display module provided by the present application, further including a border area located at least one side of the display area; the shielding layer further includes a second shielding part located in the border area.

According to the display module provided by the present application, a boundary of the second shielding part is flush with a boundary of the transparent film layer.

According to the display module provided by the present application, the second shielding part is located between the transparent film layer and the first adhesive layer, or the second shielding part is located on the side of the transparent film layer away from the display panel.

According to the display module provided by the present application, a width of the second shielding part ranges 0.8 mm to 1.2 mm in a second direction perpendicular to the first direction.

According to the display module provided by the present application, a distance from an edge of an orthographic projection of the first shielding part on the display panel to an edge of an orthographic projection of the function hole on the display panel is less than 1 mm.

According to the display module provided by the present application, further including:
a backplate and a supporting layer disposed on a side of the display panel away from the shielding layer, the supporting layer is disposed on a side of the backplate away from the shielding layer;
the function hole goes through the supporting layer, the backplate, the display panel, the filter layer, the first adhesive layer, the transparent film layer, and the first shielding part.

According to the display module provided by the present application, further including:
a cover plate protective layer disposed on a side of the cover plate away from the display panel; and
a circulating protective film disposed on a side of the cover plate protective layer away from the display panel.

According to the display module provided by the present application, a material of the shielding layer includes ink, black resin, and carbon black, and a material of the transparent film layer includes polyethylene terephthalate.

According to the display module provided by the present application, further including a photosensitive element disposed in the function hole.

The present application provides a display device, including a display module, the display module includes:
a display panel;
a cover plate layer located on a light-emitting side of the display panel;
a filter layer located on a side of the display panel adjacent to the cover plate layer, the filter layer includes a plurality of color filters and black matrixes disposed between two adjacent color filters;
a flexible composite layer located between the filter layer and the cover plate layer, the flexible composite layer includes a first adhesive layer and a transparent film layer disposed on a side of the first adhesive layer away from the display panel; and
a shielding layer located between the filter layer and the cover plate layer, the shielding layer includes a first shielding part located in the function area and in contact with a side surface of the transparent film layer;
the display module further includes a function hole which is defined in the function area, the function hole goes through the display panel, the filter layer, the first adhesive layer, the transparent film layer, and the first shielding part in a first direction, where the first direction is a thickness direction of the display module.

According to the display device provided by the present application, the first shielding part is located between the first adhesive layer and the transparent film layer, or the first shielding part is located on a side of the transparent film layer away from the display panel.

According to the display device provided by the present application, the flexible composite layer further includes a second adhesive layer located on the side of the transparent film layer away from the display panel, and the function hole goes through the display panel, the filter layer, the first adhesive layer, the transparent film layer, the first shielding part, and the second adhesive layer in the first direction.

According to the display device provided by the present application, further including a border area located at least one side of the display area; the shielding layer further includes a second shielding part located in the border area.

According to the display device provided by the present application, a boundary of the second shielding part is flush with a boundary of the transparent film layer.

According to the display device provided by the present application, the second shielding part is located between the transparent film layer and the first adhesive layer, or the second shielding part is located on the side of the transparent film layer away from the display panel.

According to the display device provided by the present application, a width of the second shielding part ranges 0.8 mm to 1.2 mm in a second direction perpendicular to the first direction.

The present application provides a manufacturing method of a display module, the display module includes a display panel and a cover plate layer located on a light-emitting side of the display panel; the manufacturing method includes:
providing the display panel including a display area and a function area surrounded by the display area;
forming a filter layer on a side of the display panel adjacent to the cover plate layer, the filter layer includes a plurality of color filters and black matrixes disposed between two adjacent color filters;
forming a flexible composite layer on a side of the filter layer adjacent to the cover plate layer, the flexible composite layer includes a first adhesive layer and a transparent film layer disposed on a side of the first adhesive layer away from the display panel;
forming a shielding layer between the filter layer and the cover plate layer, the shielding layer includes a first shielding part located in the function area and in contact with a side surface of the transparent film layer;
forming a function hole going through the display panel, the filter layer, the first adhesive layer, the transparent film layer, and the first shielding part; and
providing a cover plate layer and attaching the cover plate layer to a side of the flexible composite layer and a side of the filter layer away from the display panel.

### Beneficial Effects

Beneficial effects of the present application: The present application provides the display module and the manufacturing method thereof, and the display device. The display module includes the display area and the function area surrounded by the display area. The display module includes the display panel, the cover plate layer, the filter layer, the flexible composite layer, and the shielding layer. The flexible composite layer and the shielding layer are located between the filter layer and the cover plate layer. The shielding layer includes the first shielding part located in the function area and in contact with the side surface of the transparent film layer. In the present application, the first shielding part covers the whole function area, and the function hole goes through the display panel, the filter layer, the first adhesive layer, the transparent film layer, and the first shielding part in a thickness direction of the display module, so that a part of the first shielding part corresponding to the function hole and a deformed part of transparent film layer are simultaneously removed when the function hole is opened, thereby a deformed part of the module at a position of a camera hole may be directly removed to remove the thickness difference. This is beneficial to reduce the PV value of the position of the camera hole and improve the photographing effect of the whole machine.

### DESCRIPTION OF DRAWINGS

To describe the technical solutions of the embodiments of the present application more clearly, the following briefly introduces the accompanying drawings used in the description of the embodiments of the present application. Apparently, the accompanying drawings described below illustrate only some exemplary embodiments of the present application, and persons skilled in the art may derive other drawings from the drawings without making creative efforts.

FIG. 1 is a plan structural schematic diagram of a display module provided by an embodiment of the present application

FIG. 2 is a cross-sectional structural schematic diagram of a first display module provided by the embodiment of the present application.

FIG. 3 is a cross-sectional structural schematic diagram of a second display module provided by the embodiment of the present application.

FIG. 4 is a cross-sectional structural schematic diagram of a third display module provided by the embodiment of the present application.

FIG. 5 is a cross-sectional structural schematic diagram of a fourth display module provided by the embodiment of the present application.

FIG. 6A to FIG. 6F are schematic diagrams of manufacturing processes of the display module provided by an embodiment of the present application.

### DESCRIPTIONS OF REFERENCE NUMBERS

100, display module; 100a, function area; 1001a, function hole; 100b, display area; 100c, border area;
10, display panel; 11, cover plate layer; 12, filter layer; 13, flexible composite layer; 131, first adhesive layer; 132, transparent film layer; 133, second adhesive layer; 14, shielding layer; 141, first shielding part; 142, second shielding part; 15, backplate; 16, supporting layer; 17, cover plate protective layer; 18, circulating protective film.

### DETAILED DESCRIPTION OF EMBODIMENTS

The technical solutions in the embodiments of the present application will be described clearly and completely hereafter with reference to the accompanying drawings. Apparently, the described embodiments are only a part of but not all embodiments of the present application. All other embodiments obtained by persons of ordinary skill in the art based on the embodiments of the present application without creative efforts shall fall within the protection scope of the present application. In addition, it should be understood that the specific embodiments described herein are only used to illustrate and explain the present application and are not used to limit the present application. In the present invention, in the absence of a contrary description, the location words used, such as “up” and “down”, usually refer to the up and down under the actual use or working state of the device, specifically the drawing direction in the attached drawings; The “inside” and “outside” are for the contour of the device.

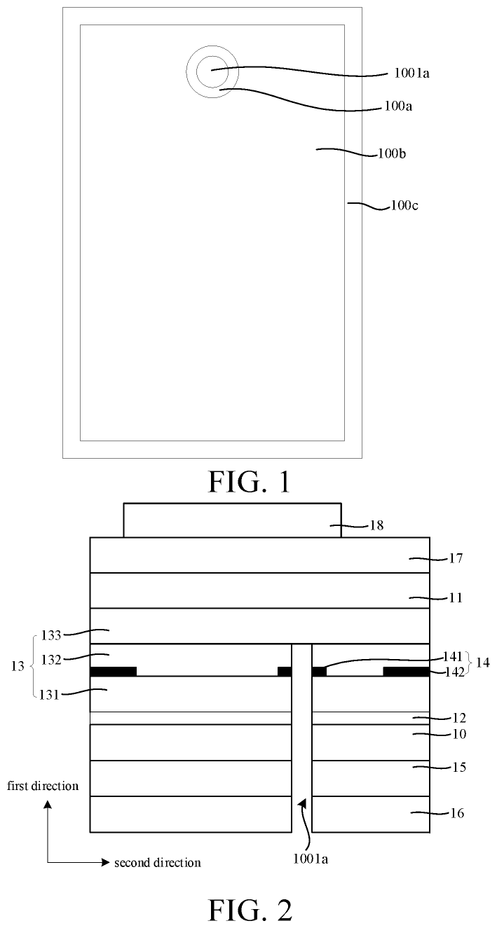

Referring to FIG. 1, the embodiments of the present application provide a display module 100. The display module 100 includes a function area 100a and a display area 100b. The function area 100a is surrounded by the display area 100b.

The display area 100b is a normal display area for realizing display screens. The function area 100a is not used for display screens, but for placing circuits and providing the function hole 1001a. A photosensitive element is disposed in the function hole 1001a. Exemplarily, the photosensitive element may be a camera, a photoelectric sensor, or other kinds of photosensitive elements known to the persons in the art, which is not limited by the embodiments of the present application. One or more of the photosensitive elements may be provided in each of the function holes 1001a. When a plurality of photosensitive elements are provided, a type and a relative position of each of the photosensitive elements may be set according to actual requirements of the display module 100, which is not limited by the embodiments of the present application.

In the embodiments of the present application, a number of the function holes 1001a and a number of the function area 100a is same. For example, the embodiments of the present application exemplarily show that the number of the function areas 100a is one, and the number of the function holes 1001a is one, which is only an exemplary description and is not limited. In addition, the embodiments of the present application further exemplarily show that plane shapes of the function area 100a and the function hole 1001a are circular respectively, which is only an exemplary description and is not limited. In other embodiments, the plane shapes of the function area 100a and the function hole 1001a may be set according to the actual requirements of the display module 100. The plane shapes of the function area 100a and the function hole 1001a may be same or different.

In order to clearly explain the technical solutions provided by the present application, the embodiments of the present application take the function hole 1001a as a camera hole, the photosensitive element as a camera, and the camera is disposed in the camera hole to realize a photographing function as an example.

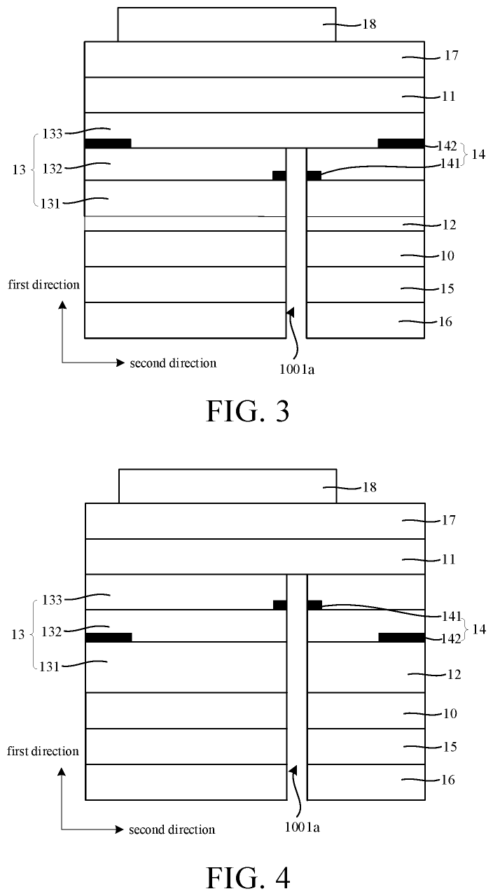

Referring to FIG. 2, the display module 100 includes a display panel 10, a cover plate layer 11, a filter layer 12, a flexible composite layer 13, and a shielding layer 14. The cover plate layer 11 is located on a light-emitting side of the display panel 10. The filter layer 12 is located on a side of the display panel 10 adjacent to the cover plate layer 11. The filter layer 12 includes a plurality of color filters (not shown in figures) and black matrixes (not shown in the figures) disposed between two adjacent color filters. The shielding layer 14 is located between the filter layer 12 and the cover plate layer 11. The shielding layer 14 includes a first shielding part 141, and the first shielding part 141 is located in the function area 100a.

It may be understood that circuits made of metal are generally disposed in an area of the function area 100a located around the function hole 1001a. Light is easy to produce reflected light on a surface of the circuits. If the reflected light enters human eyes, perception may be affected. If the reflected light enters the function hole 1001a, the photosensitive element may be disturbed. To solve this problem, in the embodiments of the present application, the first shielding part 141 is disposed in the function area 100a and located around the function hole 1001a to shield the circuits in the function area 100a.

Specifically, the shielding layer 14 may be black or dark material. Optionally, a material of the shielding layer 14 includes ink, black resin, or carbon black. These materials have better shading effect and lower cost, which is beneficial to reduce overall cost of the display module 100.

It should be noted that a peroxide value (PV) is a measurement index of surface irregularity, especially one of indexes to evaluate deformation of a mirror surface. The PV value corresponds to a difference between a peak value and a valley value of a wave surface. Improving a flatness of the camera hole is beneficial to improve a photographing effect. Specifically, the larger the PV value, the greater the surface irregularity of a material surface, and the more uneven the surface is. The smaller the PV value, the smaller the surface irregularity of the material surface, and the more even the surface is.

In the embodiments of the present application, the display module 100 may be a flexible display module. The flexible display module may be a foldable display module capable of being bent or folded. In order to improve a bending ability of the display module 100, the side of the shielding layer 14 away from the display panel 10 is further provided with a plurality of flexible film layers, and the plurality of flexible film layers include polymer films and optically clear adhesives stacked with different materials to balance the bending ability of the display module 100, which is beneficial to improve service life of the display module 100. However, a hardness of each layer of the polymer films and the optically clear adhesive is poor, and it is easy to deform during a bonding process. Particularly, the polymer films and the optically clear adhesives located around the function hole 1001a have relatively high deformation, resulting in a local high peroxide value, thereby affecting the photographing effect of a whole machine.

Exemplarily, the display module 100 further includes the flexible composite layer 13 disposed the side of the display panel 10. The flexible composite layer 13 includes a first adhesive layer 131 and a transparent film layer 132 disposed on a side of the first adhesive layer 131 away from the display panel 10. In a first direction, the function hole 1001a goes through the display panel 10, the filter layer 12, the first adhesive layer 131, the transparent film layer 132, and the first shielding part 141, and the first direction is a thickness direction of the display module 100.

It should be noted that the first shielding part 141 of the shielding layer 14 in a prior art merely covers a part of the function area 100a, that is, the first shielding part 141 merely covers an area where the function area 100a does not correspond to the function hole 1001a. The first shielding part 141 in the prior art is relatively far away from the display panel 10, so it is difficult for the function hole 1001a to dig into a film layer where the first shielding part 141 is located. The transparent film layer 132 located above the first shielding part 141 is prone to deformation when attached to the first shielding part 141, so that the PV value of the transparent film layer 132 is too large. Furthermore, there is a thickness difference between an area corresponding to the function hole 1001a and other areas, and bubbles are easily formed when the optically clear adhesives are bonded to the first shielding part 141. Meanwhile, the first shielding part 141 also squeezes the flexible films in contact with the first shielding part 141, resulting in serious deformation of the flexible films, thereby affecting the photographing effect of the camera.

In view of this, the embodiments of the present application are based on a structure of the existing display module. The flexible composite layer 13 is added on the side of the display panel 10 close to the cover plate layer 11. The shielding layer 14 at a position of the cover protective layer 17 is moved to the flexible composite layer 13. The first shielding part 141 covers the entire function area 100a. In brief, the first shielding part 141 in the embodiments of the present application changes from a circled shape to a dot shape. It may be understood that with this design, even if the first shielding part 141 squeezes a flexible film (for example, the transparent film layer 132) in contact with the first shielding part 141 which results in serious deformation of the flexible film, when the function hole 1001a is subsequently formed by a cutting process, a part of the first shielding part 141 corresponding to the function hole 1001a will be cut off, so that external light may be irradiated to the photosensitive element in the function hole 1001a. Meanwhile, when the first shielding part 141 is cut off, a deformed part of the transparent film layer 132 is also cut off, thereby the deformed part of the flexible film may be directly removed, the PV value at the position of the camera hole is reduced, the photographing effect of the whole machine is improved, and a surface depression of the display module 100 is avoided.

Specifically, when the flexible composite layer 13 and the shielding layer 14 are attached to the display panel 10, the function hole 1001a may be formed by laser drilling using a two-cut process.

Specifically, a material of the transparent film layer 132 is a transparent flexible material, which may improve a bending performance of the display module 100 and prevent the transparent film layer 132 from influencing light emission of the display panel 10. Optionally, the material of the transparent film layer 132 includes polyethylene terephthalate (PET), etc.

Specifically, the first adhesive layer 131 is used to adhere the display panel 10 and the transparent film layer 132. Optionally, a material of the first adhesive layer 131 may be an optically clear adhesive (OCA).

In the embodiments of the present application, a distance from an edge of an orthographic projection of the first shielding part 141 on the display panel 10 to an edge of an orthographic projection of the function hole 1001a on the display panel 10 is greater than 0.5 mm, and less than 1 mm. A reason for this setting is that the distance from the edge of the orthographic projection of the first shielding part 141 on the display panel 10 to the edge of the orthographic projection of the function hole 1001a on the display panel 10 may not be too large or too small. Specifically, if the distance above-mentioned is too large, a thickness of a part of the first shielding part 141 located in the function area 100a will be uneven, thereby the transparent film layer 132 located above the first shielding part 141 is deformed. Relatively speaking, if the distance above-mentioned is too small, the circuits located in the function area 100a may not be completely shielded.

Optionally, the distance from the edge of the orthographic projection of the first shielding part 141 on the display panel 10 to the edge of the orthographic projection of the function hole 1001a on the display panel 10, is equal to a distance from an edge of the function hole 1001a to an edge of the function hole 1001a.

It should be noted that the shielding part 14 is formed by coating drying resin or carbon black. A thickness of the shielding part 14 is not set too thin, or the shielding part 14 is easy to shrink after being dried, so that a plurality of holes will be formed on the shielding layer 14, resulting in light leakage. In addition, carbon black added has different sizes, and if the thickness of the shielding layer 14 is too thin, there is a gap in a middle of carbon black, resulting in substandard optical density (OD) and poor shielding effect.

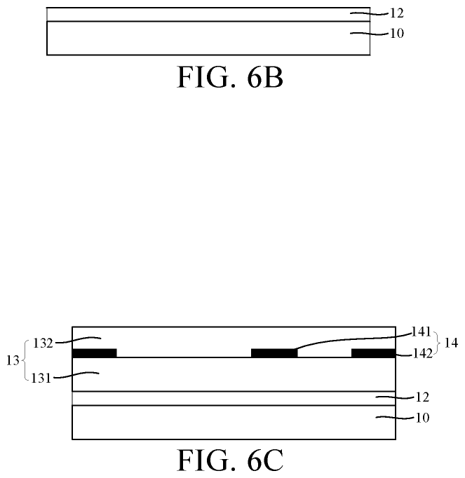

In an embodiment, as shown in FIG. 2, the first shielding part 141 is located between the first adhesive layer 131 and the transparent film layer 141. At this time, the deformed part of the transparent film layer 132 is protruded upward relative to the display panel 10, and the function hole 1001a goes through the transparent film layer 132 to remove the deformed part protruded upward. In another embodiment, as shown in FIG. 4, the first shielding part 141 is located on the side of the transparent film layer 132 away from the display panel 10. At this time, the deformed part of the transparent film layer 132 is recessed downward relative to the display panel 10, and the function hole 1001a goes through the transparent film layer 132 to remove the deformed part recessed downward.

Furthermore, as shown in FIG. 2 to FIG. 5, the flexible composite layer 13 further includes a second adhesive layer 133. The second adhesive layer 133 is located on the side of the transparent film layer 132 away from the display panel 10. Optionally, a material of the second adhesive layer 133 and the material of the first adhesive layer 131 may be same. For example, the material of the second adhesive layer 133 includes the optically clear adhesive.

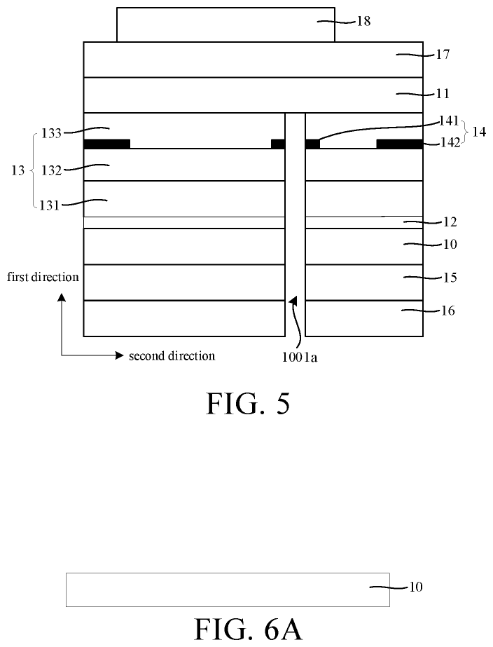

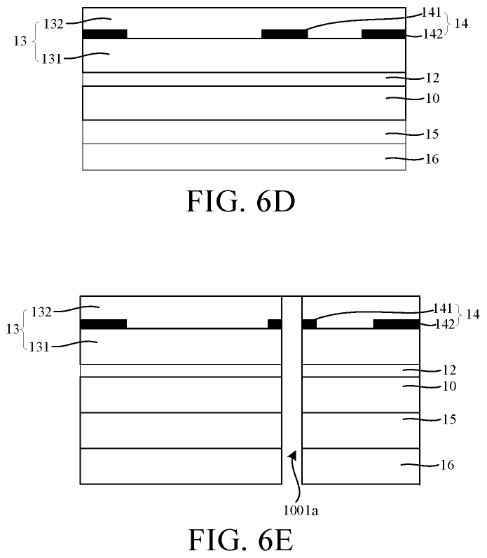

Exemplarily, as shown in FIG. 2 and FIG. 3, since the first shielding part 141 is not in contract with the second adhesive layer 133, there is no deformation of the second adhesive layer 133 resulting from an arrangement of the first shielding part 141. At this time, the function hole 1001a may be designed not to go through the second adhesive layer 133. As shown in FIG. 4 and FIG. 5, the first shielding part 141 is in contract with the second adhesive layer 133, since the hardness of the optically clear adhesive is poor, the second adhesive layer 133 is pone to deformation when be attached, and a deformed part of the second adhesive layer 133 may also lead to an increase of the PV value of the position of the camera hole. When the first shielding part 141 is cut off, the deformed part of the second adhesive layer 133 is also cut off, thereby the deformed part of the second adhesive layer 133 may be directly removed, the PV value of the position of the camera hole is reduced, and the photographing effect of the whole machine is further improved.

Referring to FIG. 1 to FIG. 5, the display module 100 further includes a border area 100c located on at least one side of the display area 100b. The border area 100c is used to place external circuits, such as gate driving circuits and the like. The shielding layer 14 further includes a second shielding part 142 located in the border area 100c, and the second shielding part 142 is used to shield the external circuits disposed in the border area 100c. In addition, the second shielding part 142 is further used to shield the light emitted from the display panel 10, thereby reducing or even avoiding a problem of the light leakage at an edge of the display area 100b. It should be noted that the border area 100c may be disposed around the display area 100b, and may be disposed at one side, two sides, or three sides of the display area 100b, which is not limited in the present application. For example, the embodiments of the present application will be described by taking the border area 100c located around the display area 100b as an example.

The flexible composite layer 13 is composited by the transparent film layer 132 and the first adhesive layer 131. A modulus of the first adhesive layer 131 for folding is generally low, and a fluidity of the first adhesive layer 131 is good. During processes of cutting, transporting, and using the display module 100, the first adhesive layer 131 easily overflows an edge of the transparent film layer 132, resulting in glue overflow. Furthermore, both a width of the glue overflow and a uniformity of the glue overflow are difficult to control, resulting in poor stability of the first adhesive layer 131. When the flexible composite layer 13 is attached to one side of the display panel 10, a dispensing process is required. Specifically, it is necessary to grasp the edge of the flexible composite layer 13 as a relative position reference line for dispensing. The flexible composite layer 13 is completely transparent, and a boundary of the flexible composite layer 13 is not clear. Furthermore, a thickness of the flexible composite layer 13 is smaller, which is generally less than 100 um, so that a recognition degree of the edge of the flexible composite layer 13 is poor, or even unrecognizable, and is easily affected by the glue overflow of the edge. The greater a fluctuation of the glue overflow, the worse a dispensing accuracy, which is not conducive to production.

In view of this, in the embodiments of the present application, a boundary of the second shielding part 142 is flush with the boundary of the transparent film layer 132 in the first direction. A reason for this setting is that the second shielding part 142 is added on the edge of the transparent film layer 132, that is, the second shielding part 142 is disposed on a position of the flexible composite layer 13 corresponding to the border area 100c. Since the second shielding part 142 is colored and opaque, an edge of the second shielding part 142 is highly recognizable and easy to be recognized. Furthermore, since the edge of the second shielding part 142 is relatively neat, and a width of the second shielding part 142 is highly controllable. The edge of the second shielding part 142 is suitable for dispensing as the relative position reference line, which may provide a stable reference position for dispensing, thereby effectively improving the dispensing accuracy.

Specifically, in actual manufacturing processes, the edge of the second shielding part 142 is generally extended beyond the edge of the transparent film layer 132. Then, the transparent film layer 132 and the second shielding part 142 are trimmed by laser, so that the boundary of the second shielding part 142 is flush with the boundary of the transparent film layer 132.

Optionally, the second shielding part 142 and the first shielding part 141 may be disposed in a same layer or in different layers. The second shielding part 142 and the first shielding part 141 may be disposed the side of the first adhesive layer 131 away from the display panel 10. The second shielding part 142 and the first shielding part 141 may also be disposed the side of the transparent film layer 132 away from the display panel 10.

Exemplarily, as shown in FIG. 2 and FIG. 5, the second shielding part 142 and the first shielding part 141 may be disposed in the same layer. Specifically, as shown in FIG. 2, the second shielding part 142 is located between the transparent film layer 132 and the first adhesive layer 131, and the first shielding part 141 is located between the transparent film layer 132 and the first adhesive layer 131. Or, as shown in FIG. 5, the second shielding part 142 is located on the side of the transparent film layer 132 away from the display panel 10, and the first shielding part 141 is located on the side of the transparent film layer 132 away from the display panel 10.

Exemplarily, as shown in FIG. 3 and FIG. 4, the second shielding part 142 and the first shielding part 141 may be disposed in different layers. Specifically, as shown in FIG. 3, the second shielding part 142 is located on the side of the transparent film layer 132 away from the display panel 10, and the first shielding part 141 is located between the transparent film layer 132 and the first adhesive layer 131. Or, as shown in FIG. 4, the second shielding part 142 is located between the transparent film layer 132 and the first adhesive layer 131, and the first shielding part 141 is located on the side of the transparent film layer 132 away from the display panel 10.

In the embodiments of the present application, the width of the second shielding part 142 ranges 0.8 mm to 1.2 mm in a second direction. Certainly, in other embodiments, the width of the second shielding part 142 may be disposed in other ranges, which may be adaptively adjusted according to the actual requirements. It may be understood that the width of the second shielding part 142 depends on a width of the border area 100c in the second direction. Certainly, the width of the second shielding part 142 may not be too small, otherwise, the edge of the second shielding part 142 as the relative position reference line is not clear, and the dispensing accuracy is affected.

It may be understood that the shielding layer 14 in the embodiments of the present application is disposed at the position of the transparent film layer 132. A structure of the transparent film layer 132 is relatively simple, so that manufacturing the shielding layer 14 is relatively easy. Compared that the shielding layer 14 in the prior art is disposed at the position of the cover protective layer 17, the manufacturing processes of the embodiment of the disclosure are simple, which is beneficial to improving yield and reducing production cost.

Furthermore, as shown in FIG. 2 to FIG. 5, in the embodiments of the present application, the display module 100 further includes a backplate 15 and a supporting layer 16. Specifically, the backplate 15 and the supporting layer 16 are disposed on a side of the display panel 10 away from the shielding layer 14. The supporting layer 16 is disposed on a side of the backplate 15 away from the shielding layer 14. The function hole 1001a goes through the supporting layer 16, the backplate 15, the display panel 10, the filter layer 12, the first adhesive layer 131, the transparent film layer 132, and the first shielding part 141.

Furthermore, the display module 100 further includes the cover protective layer 17 and a circulating protective film (CPF) 18. The cover plate layer 11 is disposed on a side of the second adhesive layer 133 away from the display panel 10. The cover protective layer 17 is disposed on a side of the cover plate layer 11 away from the display panel 10. The circulating protective film 18 is disposed on a side of the cover protective layer 17 away from the display panel 10.

Specifically, the supporting layer 16 is used to support the display panel 10. A material of the supporting layer 16 may be, for example, SUS (stainless steel) or the like. A material of the cover plate layer 11 may include ultra-thin glass, transparent polyimide, or other material with high light transmittance. The cover protective layer 17 is used to protect the cover plate layer 11. The cover protective layer 17 may include a base substrate and a hardened coating layer stacked. The hardened coating layer is located on a side of the substrate away from the display panel 10 to play an anti-scratch role. The base substrate is generally made of PET material, and the base substrate may be made of foldable films such as CPI (Colorless polyimide) and the like.

The display panel 10 may be an organic light-emitting diode display (OLED) panel, an electroluminescent display panel, etc. For example, the embodiments of the present application are described by taking the display panel 10 as the OLED panel as an example. The filter layer 12 is disposed on the display panel 10, that is, the display panel 10 is a pol-less display panel. Since a polarizer in the prior art is removed, the bending ability of the display module 100 may be improved. In addition, the polarizer is used to reduce the reflected light of the metal circuits on the display panel 10. The polarizer is generally disposed close to the display panel 10 to obtain a better effect of reducing the reflected light. There is a difference from the prior art that the embodiments of the present application combine the pol-less display panel with the shielding layer 14. Since the polarizer is removed, the flexible composite layer 13 may be disposed closer to the display panel 10, regardless of a position of the polarizer. In addition, removing the polarizer enables the function hole 1001a to go through the flexible composite layer 13.

Specifically, the display panel 10 includes a driving circuit layer, a light-emitting function layer, and an encapsulation layer stacked in sequence. The light-emitting function layer is located on the driving circuit layer. The encapsulation layer is located on the driving circuit layer. The driving circuit layer may include a plurality of pixel driving circuits, and the pixel driving circuits may be one of a 2T1C pixel circuit, a 3T1C pixel circuit, a 5T1C pixel circuit, and a 7T1C pixel circuit. The driving circuit layer may include a substrate, an active layer, a gate insulating layer, a gate layer, an interlayer insulating layer, a source-drain electrode layer, a planarization layer, etc., which are stacked in sequence. Certainly, it is well known in the art that the driving circuit layer may also be other structures, as long as a corresponding driving current may be provided for the light-emitting function layer. The light-emitting function layer may include a hole injection layer, a hole transport layer, an electron blocking layer, a light-emitting layer, a hole blocking layer, an electron transport layer, and an electron injection layer stacked in sequence. The light-emitting function layer may be other structures. The encapsulation layer may be in a form of, for example, a film encapsulation, a frit (glass powder) encapsulation, a conventional encapsulation, or the like.

It should be noted that descriptions above-mentioned of the film structure of the display panel 10 are related to the prior art, which will not be described in detail here.

The embodiments of the present application further provide a display device. The display device includes the display module 100 in the embodiments above-mentioned. The display device may be, for example, personal electronic devices such as mobile phones, tablet computers, notebook computers, and the like, and may also be used in self-service vending machines, bank automatic terminals, and other display devices requiring face recognition. Since the display device includes the display module 100 provided by any one of the embodiments of the present application, the same beneficial effects are also provided and will not be repeated here.

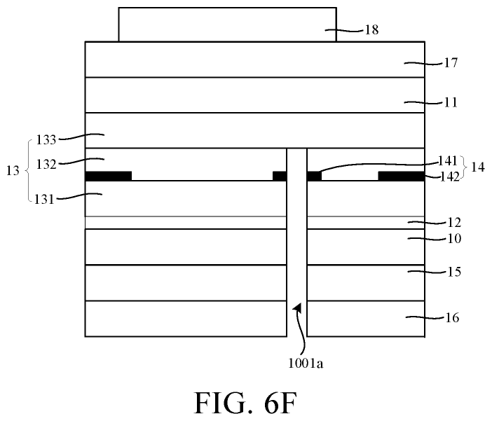

Referring to FIG. 6A to FIG. 6F, the embodiments of the present application further provide a manufacturing method of the display module 100. The display module 100 includes a display panel 10 and a cover plate layer 11 located on a light-emitting side of the display panel 10.

The manufacturing method includes:
step S10, providing the display panel 10 including a display area 100a and a function area 100b surrounded by the display area 100a.
step S20, forming a filter layer 12 on a side of the display panel 10 adjacent to the cover plate layer 11, where the filter layer 12 includes a plurality of color filters and black matrixes disposed between two adjacent color filters.
step S30, forming a flexible composite layer 13 on a side of the filter layer 12 adjacent to the cover plate layer 11, where the flexible composite layer 13 includes a first adhesive layer 131 and a transparent film layer 132 disposed on a side of the first adhesive layer 131 away from the display panel 10.
step S40, forming a shielding layer 14 between the filter layer 12 and the cover plate layer 11, where the shielding layer 14 includes a first shielding part 141 located in the function area 100a and in contact with a side surface of the transparent film layer 132.
step S50, providing a function hole 100a going through the display panel 10, the filter layer 12, the first adhesive layer 131, the transparent film layer 132, and the first shielding part 141. And
step S60, providing the cover plate layer 11 and attaching the cover plate layer 11 to a side of the flexible composite layer 13 and a side of the filter layer 12 away from the display panel 10.

Exemplarily, taking the structure of the display module 100 in FIG. 2 as an example. Specifically, as shown in FIG. 6A, in the step S10, the display panel 10 is a flexible display panel. The display panel 10 further includes a border area 100c located on at least one side of the display area 100b. As shown in FIG. 6B, in the step S20, the filter layer 12 is directly disposed on the display panel 10, thereby removing a polarizer.

As shown in FIG. 6C, in the step S30 and the step S40, after forming the first adhesive layer 131, the shielding layer 14 is formed on a side of the first adhesive layer 131 away from the display panel 10, and the shielding layer 14 includes the first shielding part 141 located in the function area 100a. After forming the first shielding part 141, the transparent film layer 132 covering the shielding layer 14 is formed. After forming the transparent film layer 132, a dispensing treatment is performed between the transparent film layer 132 and the display panel 10 by a dispensing process. Furthermore, the shielding layer 14 further includes a second shielding part 142 formed in the border area 100c.

As shown in FIG. 6D, before the step S50, the manufacturing method further includes: forming a second adhesive layer 133 on a side of the transparent film layer 132 away from the display panel 10; forming a backplate 15 on a side of the display panel 10 away from the shielding layer 14; and forming the supporting layer 16 on a side of the backplate 15 away from the display panel 10.

As shown in FIG. 6E, in the step S50, the function hole 1001a is formed by a two-cutting process. The function hole 1001a goes through the display panel 10, the filter layer 12, the first adhesive layer 131, the first shielding part 141, and the transparent film layer 132.

As shown in FIG. 6F, in the step S60, the step S60 further includes: forming a cover plate protective layer 17 on a side of the cover plate layer 11 away from the display panel 10; and forming a circulating protective film 18 on a side of the cover protective layer 17 away from the display panel 10.

It may be understood that in the manufacturing method provided by the embodiments of the present application, the first shielding part 141 is formed in the function area 100a. When forming the first shielding part 141, the first shielding part 141 corresponding to the function hole 1001a is cut by the two-cut process. In addition, by providing the first shielding part 141, a deformed part of the transparent film layer 132 located on the first shielding part 141 is also removed, so that the deformed part of the module at the position of the camera hole may be directly removed, and the PV value of the position of the camera hole is reduced, which is beneficial to improve the photographing effect of the whole machine.

Beneficial effects of the present application: The present application provides the display module and the manufacturing method thereof, and the display device. The display module includes the display area and the function area surrounded by the display area. The display module includes the display panel, the cover plate layer, the filter layer, the flexible composite layer, and the shielding layer. The flexible composite layer and the shielding layer are located between the filter layer and the cover plate layer. The shielding layer includes the first shielding part located in the function area and in contact with the side surface of the transparent film layer. In the present application, the first shielding part covers the whole function area, and the function hole goes through the display panel, the filter layer, the first adhesive layer, the transparent film layer, and the first shielding part in the thickness direction of the display module, so that the part of the first shielding part corresponding to the function hole and the deformed part of transparent film layer are simultaneously removed when the function hole is opened, thereby the deformed part of the module at the position of the camera hole may be directly removed to remove the thickness difference. This is beneficial to reduce the PV value of the position of the camera hole and improve the photographing effect of the whole machine.

The embodiments of the present application are described in detail above. The principle and implementations of the present application are described in this specification by using specific examples. The description about the foregoing embodiments is merely provided to help understand the method and core ideas of the present application. In addition, persons of ordinary skill in the art can make modifications in terms of the specific implementations and disclosure scopes according to the ideas of the present application. Therefore, the content of this specification shall not be construed as a limit to the present application.

1. A display module, provided with a display area and a function area surrounded by the display area, the display module comprising:
a display panel;
a cover plate layer located on a light-emitting side of the display panel;
a filter layer located on a side of the display panel adjacent to the cover plate layer, wherein the filter layer comprises a plurality of color filters and black matrixes disposed between two adjacent color filters;
a flexible composite layer located between the filter layer and the cover plate layer, wherein the flexible composite layer comprises a first adhesive layer and a transparent film layer disposed on a side of the first adhesive layer away from the display panel; and
a shielding layer located between the filter layer and the cover plate layer, wherein the shielding layer comprises a first shielding part located in the function area and in contact with a side surface of the transparent film layer;
wherein the display module further comprises a function hole which is defined in the function area, the function hole goes through the display panel, the filter layer, the first adhesive layer, the transparent film layer, and the first shielding part in a first direction, where the first direction is a thickness direction of the display module.

2. The display module according to claim 1, wherein the first shielding part is located between the first adhesive layer and the transparent film layer, or the first shielding part is located on a side of the transparent film layer away from the display panel.

3. The display module according to claim 2, wherein the flexible composite layer further comprises a second adhesive layer located on the side of the transparent film layer away from the display panel, and the function hole goes through the display panel, the first adhesive layer, the transparent film layer, the first shielding part, and the second adhesive layer in the first direction.

4. The display module according to claim 1, further comprising a border area located at least one side of the display area, wherein the shielding layer further comprises a second shielding part located in the border area.

5. The display module according to claim 4, wherein a boundary of the second shielding part is flush with a boundary of the transparent film layer.

6. The display module according to claim 5, wherein the second shielding part is located between the transparent film layer and the first adhesive layer, or the second shielding part is located on the side of the transparent film layer away from the display panel.

7. The display module according to claim 6, wherein a width of the second shielding part ranges 0.8 mm to 1.2 mm in a second direction perpendicular to the first direction.

8. The display module according to claim 1, wherein a distance from an edge of an orthographic projection of the first shielding part on the display panel to an edge of an orthographic projection of the function hole on the display panel is less than 1 mm.

9. The display module according to claim 1, further comprising:
a backplate and a supporting layer disposed on a side of the display panel away from the shielding layer, wherein the supporting layer is disposed on a side of the backplate away from the shielding layer; wherein the function hole goes through the supporting layer, the backplate, the display panel, the filter layer, the first adhesive layer, the transparent film layer, and the first shielding part.

10. The display module according to claim 9, further comprising:
a cover plate protective layer disposed on a side of the cover plate away from the display panel; and
a circulating protective film disposed on a side of the cover plate protective layer away from the display panel.

11. The display module according to claim 1, wherein a material of the shielding layer comprises ink, black resin, and carbon black, and a material of the transparent film layer comprises polyethylene terephthalate.

12. The display module according to claim 1, further comprising a photosensitive element disposed in the function hole.

13. A display device, comprising a display module, the display module comprising:
a display panel;
a cover plate layer located on a light-emitting side of the display panel;
a filter layer located on a side of the display panel adjacent to the cover plate layer, wherein the filter layer comprises a plurality of color filters and black matrixes disposed between two adjacent color filters;
a flexible composite layer located between the filter layer and the cover plate layer, wherein the flexible composite layer comprises a first adhesive layer and a transparent film layer disposed on a side of the first adhesive layer away from the display panel; and
a shielding layer located between the filter layer and the cover plate layer, wherein the shielding layer comprises a first shielding part located in the function area and in contact with a side surface of the transparent film layer;
wherein the display module further comprises a function hole which is defined in the function area, the function hole goes through the display panel, the filter layer, the first adhesive layer, the transparent film layer, and the first shielding part in a first direction, where the first direction is a thickness direction of the display module.

14. The display device according to claim 13, wherein the first shielding part is located between the first adhesive layer and the transparent film layer, or the first shielding part is located on a side of the transparent film layer away from the display panel.

15. The display device according to claim 14, wherein the flexible composite layer further comprises a second adhesive layer located on the side of the transparent film layer away from the display panel, and the function hole goes through the display panel, the filter layer, the first adhesive layer, the transparent film layer, the first shielding part, and the second adhesive layer in the first direction.

16. The display device according to claim 13, wherein further comprising a border area located at least one side of the display area; wherein the shielding layer further comprises a second shielding part located in the border area.

17. The display device according to claim 16, wherein a boundary of the second shielding part is flush with a boundary of the transparent film layer.

18. The display device according to claim 17, wherein the second shielding part is located between the transparent film layer and the first adhesive layer, or the second shielding part is located on the side of the transparent film layer away from the display panel.

19. The display device according to claim 18, wherein a width of the second shielding part ranges 0.8 mm to 1.2 mm in a second direction perpendicular to the first direction.

20. A manufacturing method of a display module, comprising:
providing a display panel comprising a display area and a function area surrounded by the display area;
forming a filter layer on a side of the display panel, wherein the filter layer comprises a plurality of color filters and black matrixes disposed between two adjacent color filters;
forming a flexible composite layer on a side of the filter layer, wherein the flexible composite layer comprises a first adhesive layer and a transparent film layer disposed on a side of the first adhesive layer away from the display panel;
forming a shielding layer on the side of the filter layer, wherein the shielding layer comprises a first shielding part located in the function area and in contact with a side surface of the transparent film layer;
forming a function hole going through the display panel, the filter layer, the first adhesive layer, the transparent film layer, and the first shielding part; and
providing a cover plate layer and attaching the cover plate layer to a side of the flexible composite layer and a side of the filter layer away from the display panel.
